(19) United States
(12) Patent Application Publication
(10) Pub. No.: US 2023/0230987 A1
(43) Pub. Date: Jul. 20, 2023

(54) IMAGING SYSTEMS, AND IMAGE PIXELS AND RELATED METHODS

(71) Applicant: SEMICONDUCTOR COMPONENTS INDUSTRIES, LLC, Phoenix, AZ (US)

(72) Inventors: Byounghee LEE, Boise, ID (US); Swarnal BORTHAKUR, Boise, ID (US); Marc Allen SULFRIDGE, Boise, ID (US)

(73) Assignee: SEMICONDUCTOR COMPONENTS INDUSTRIES, LLC, Phoenix, AZ (US)

(21) Appl. No.: 18/065,992

(22) Filed: Dec. 14, 2022

Related U.S. Application Data
(60) Provisional application No. 63/266,804, filed on Jan. 14, 2022.

(51) Int. Cl. H01L 27/146; H04N 25/131

(52) U.S. Cl. CPC H01L 27/14621; H01L 27/14627; H04N 25/131

(57) ABSTRACT

Imaging systems, and image pixels and related methods. At least one example is an image sensor comprising a plurality of image pixels. Each image pixel may comprise: a color router defining a router collection area on an upper surface; a first photosensitive region beneath the color router; a second photosensitive region beneath the color router; and a third photosensitive region beneath the color router. The color router may be configured to route photons of a first wavelength received at the router collection area to the first photosensitive region, route photons of a second wavelength received at the router collection area to the second photosensitive region, and route photons of a third wavelength received at the router collection area to the third photosensitive region.

### CROSS-REFERENCE TO RELATED APPLICATIONS

This application claims the benefit of U.S. Prov. App. No. 63/266,804 filed Jan. 14, 2022 titled “Nanophotonic Color Filter and Lens.” The provisional application is incorporated by reference herein as if reproduced in full below.

### BACKGROUND

Image sensors are used in electronic devices such as cellular telephones, cameras, and computers to capture images. In particular, an electronic device is provided with an array of image pixels arranged in a grid pattern. Each image pixel receives incident photons, such as light, and converts the photons into electrical signals. Many image sensors suffer from low-light sensitivity. That is, in low light situations, such as dawn or dusk, insufficient photons may be captured to recreate a suitable image.

### SUMMARY

One example is an image sensor comprising a plurality of image pixels. Each image pixel may comprise: a color router defining a router collection area on an upper surface; a first photosensitive region beneath the color router; a second photosensitive region beneath the color router; and a third photosensitive region beneath the color router. The color router may be configured to route photons of a first wavelength received at the router collection area to the first photosensitive region, route photons of a second wavelength received at the router collection area to the second photosensitive region, and route photons of a third wavelength received at the router collection area to the third photosensitive region.

In the example image sensor, when the color router routes photons of a first wavelength, the color router may be further configured to route photons having a wavelength corresponding to red to the first photosensitive region, and when the color router routes photons of a second wavelength the color router may be further configured to route photons having a wavelength corresponding to yellow to the second photosensitive region, and when the color router routes photons of a third wavelength the color router is further configured to route photons having a wavelength corresponding to cyan to the third photosensitive region.

In the example image sensor, when the color router routes photons of a first wavelength the color router may be further configured to route photons having a wavelength corresponding to red to the first photosensitive region, when the color router routes photons of a second wavelength the color router may be further configured to route photons having a wavelength corresponding to yellow to the second photosensitive region; and when the color router routes photons of a third wavelength the color router may be further configured to route photons having a wavelength corresponding to blue to the third photosensitive region.

In the example image sensor, each image pixel may further comprise a fourth photosensitive region beneath the color router. When the color router routes photons of a first wavelength, the color router may be further configured to route photons having a wavelength corresponding to red to the first photosensitive region, when the color router routes photons of a second wavelength the color router may be further configured to route photons having a wavelength corresponding to yellow to the second photosensitive region, and when the color router routes photons of a third wavelength the color router may be further configured to route photons having a wavelength corresponding to green to the third photosensitive region, and the color router may be further configured to route photons having a wavelength corresponding to blue to the fourth photosensitive region.

In the example image sensor, each image pixel may further comprise a fourth photosensitive region beneath the color router. When the color router routes photons of a first wavelength the color router may be further configured to route photons having a wavelength corresponding to red to the first photosensitive region, when the color router routes photons of a second wavelength the color router may be further configured to route photons having a wavelength corresponding to green to the second photosensitive region, when the color router routes photons of a third wavelength the color router may be further configured to route photons having a wavelength corresponding to blue to the third photosensitive region, and the color router may be further configured to route photons having a wavelength corresponding to infrared to the fourth photosensitive region.

The example image sensor may further comprise: the first photosensitive region defining a first collection area; the second photosensitive region defining a second collection area smaller than the first collection area; and the third photosensitive region defining a third collection area smaller than the second collection area. The first wavelength may be is longer than the second wavelength, and the second wavelength may be longer than the first wavelength. The first wavelength may correspond to red, the second wavelength may correspond to blue, and the third wavelength may correspond to green. The first wavelength may correspond to a first infrared wavelength, the second wavelength may correspond to a second infrared wavelength different than the first wavelength, and the third wavelength may correspond to a third infrared wavelength. The example image sensor may further comprise a fourth photosensitive region beneath the color router, the fourth photosensitive region defining a fourth collection area larger than the first collection area, and the color router may be configured to route photons of a fourth wavelength to the fourth photosensitive region, the fourth wavelength longer than the first wavelength. The first wavelength may correspond to red, the second wavelength may correspond to blue, the third wavelength may correspond to green, and the fourth wavelength may correspond to infrared.

In the example image sensor, each image pixel may defines a long dimension measured parallel to the router collection area, and each image pixel further comprises: the first photosensitive region defines a collection area defining first shape; the second photosensitive region defines a collection area defining second shape; and the third photosensitive region defines a collection area defining third shape. The first shape, the second shape, and the third shape may be configured such that the longest horizontal distance a photon is routed through the color router is half the long dimension.

In the example image sensor, the color router may defines a first quadrant and a second quadrant. The first photosensitive region may define a composite collection area made up of a plurality of discrete photosensitive regions, and wherein the plurality of discrete photosensitive regions are equally divided beneath the first quadrant and the second quadrant. And the color router may be further configured to route photons of the first wavelength that arrive within the first quadrant to discrete photosensitive regions directly beneath the first quadrant, and to route photons of the first wavelength that arrive within the second quadrant to discrete photosensitive regions directly beneath the second quadrant. The example image sensor may further comprise an imaging controller operatively coupled to the first photosensitive region. The imaging controller may be configured to detect a phase imbalance based on a different number of photons arriving in the first quadrant compared to the second quadrant, and to modify a focus parameter based on the phase imbalance.

The example image sensor may further comprise a collimator disposed above the color router.

Another example is an imaging system comprising: an imaging controller and a camera module. The camera module may comprise: a lens system coupled to the imaging controller; and a plurality of image pixels in operational relationship to the lens system and communicatively coupled to the imaging controller. Each image pixel may comprise: a color router defining a router collection area on an upper surface; a first photosensitive region beneath the color router; a second photosensitive region beneath the color router; and a third photosensitive region beneath the color router. The color router may be configured to route photons of a first wavelength received at the router collection area to the first photosensitive region, route photons of a second wavelength received at the router collection area to the second photosensitive region, and route photons of a third wavelength received at the router collection area to the third photosensitive region.

In the example imaging system, the imaging controller and camera module may be associated with an automobile.

In the example image sensor, when the color router routes photons of a first wavelength the color router may be further configured to route photons having a wavelength corresponding to red to the first photosensitive region, when the color router routes photons of a second wavelength the color router may be further configured to route photons having a wavelength corresponding to yellow to the second photosensitive region, and when the color router routes photons of a third wavelength the color router may be further configured to route photons having a wavelength corresponding to cyan to the third photosensitive region.

In the example image system, when the color router routes photons of a first wavelength the color router may be further configured to route photons having a wavelength corresponding to red to the first photosensitive region, when the color router routes photons of a second wavelength the color router may be further configured to route photons having a wavelength corresponding to yellow to the second photosensitive region, and when the color router routes photons of a third wavelength the color router may be further configured to route photons having a wavelength corresponding to blue to the third photosensitive region.

In the example image system, each image pixel may further comprise a fourth photosensitive region beneath the color router. And when the color router routes photons of a first wavelength the color router may be further configured to route photons having a wavelength corresponding to red to the first photosensitive region, when the color router routes photons of a second wavelength the color router may be further configured to route photons having a wavelength corresponding to yellow to the second photosensitive region, when the color router routes photons of a third wavelength the color router may be further configured to route photons having a wavelength corresponding to green to the third photosensitive region, and the color router may be further configured to route photons having a wavelength corresponding to blue to the fourth photosensitive region.

In the example image system, each image pixel may further comprises a fourth photosensitive region beneath the color router. And when the color router routes photons of a first wavelength the color router may be further configured to route photons having a wavelength corresponding to red to the first photosensitive region, when the color router routes photons of a second wavelength the color router is further configured to route photons having a wavelength corresponding to green to the second photosensitive region, when the color router routes photons of a third wavelength the color router may be further configured to route photons having a wavelength corresponding to blue to the third photosensitive region, and the color router may be further configured to route photons having a wavelength corresponding to infrared to the fourth photosensitive region.

The example image system the first photosensitive region may define a first collection area, the second photosensitive region may define a second collection area smaller than the first collection area, and the third photosensitive region may define a third collection area smaller than the second collection area. The first wavelength may be longer than the second wavelength, and the second wavelength may be longer than the first wavelength. The first wavelength may correspond to red, the second wavelength may correspond to blue, and the third wavelength may correspond to green. The first wavelength may correspond to a first infrared wavelength, the second wavelength may correspond to a second infrared wavelength different than the first wavelength, and the third wavelength may corresponds to a third infrared wavelength. The example imaging sensor

The example imaging system may further comprise a fourth photosensitive region beneath the color router, the fourth photosensitive region defining a fourth collection area larger than the first collection area. The may be configured to route photons of a fourth wavelength to the fourth photosensitive region, the fourth wavelength longer than the first wavelength. The first wavelength may corresponds to red, the second wavelength may correspond to blue, the third wavelength may correspond to green, and the fourth wavelength may correspond to infrared.

The example imaging system each image pixel may define a long dimension measured parallel to the router collection area, and each image pixel may further comprise: the first photosensitive region defines a collection area defining first shape; the second photosensitive region defines a collection area defining second shape; and the third photosensitive region defines a collection area defining third shape. The first shape, the second shape, and the third shape may be configured such that the longest horizontal distance a photon is routed through the color router is half the long dimension.

In the example imaging system the color router may defines a first quadrant and a second quadrant, the first photosensitive region may define a composite collection area made up of a plurality of discrete photosensitive regions, and the plurality of discrete photosensitive regions may be equally divided beneath the first quadrant and the second quadrant. The color router may be further configured to route photons of the first wavelength that arrive within the first quadrant to discrete photosensitive regions directly beneath the first quadrant, and to route photons of the first wavelength that arrive within the second quadrant to discrete photosensitive regions directly beneath the second quadrant. The example imaging system may further comprise an imaging controller operatively coupled to the first photosensitive region. The imaging controller may be configured to detect a phase imbalance based on a different number of photons arriving in the first quadrant compared to the second quadrant, and to modify a focus parameter based on the phase imbalance.

The example imaging system may further comprise a collimator disposed above the color router.

Yet still other examples are methods of operating an image sensor, the method comprising: directing photons from a scene into a color router positioned above a plurality of photosensitive regions; routing, by the color router, photons of a first wavelength to a first photosensitive region beneath the color router; routing photons of a second wavelength to a second photosensitive region beneath the color router; and routing photons of a third wavelength to a third photosensitive region beneath the color router.

In the example method, the first wavelength may correspond to red, the second wavelength may correspond to yellow, and the third wavelength may correspond to cyan.

In the example method, the first wavelength may correspond to red, the second wavelength may correspond to yellow, and the third wavelength may correspond to blue.

In the example method, the first wavelength may corresponds to red, the second wavelength may correspond to yellow, and the third wavelength may correspond to green/The method may further comprise routing, by the color router, photons of a fourth wavelength corresponding to blue to a fourth photosensitive region beneath the color router.

In the example method, the first wavelength may correspond to red, the second wavelength may correspond to green, and the third wavelength may correspond to blue. The method may further comprise routing, by the color router, photons of a fourth wavelength corresponding to infrared to a fourth photosensitive region beneath the color router.

In the example method, the first photosensitive region may define a first collection area, the second photosensitive region may define a second collection area smaller than the first collection area, and the third photosensitive region may define a third collection area smaller than the second collection area. The first wavelength may be longer than the second wavelength, and the second wavelength may be longer than the third wavelength. The first wavelength may correspond to red, the second wavelength may correspond to blue, and the third wavelength may correspond to green. The first wavelength may correspond to a first infrared wavelength, the second wavelength may correspond to a second infrared wavelength, and the third wavelength may correspond to a third infrared wavelength. The example method may further comprise routing, by the color router, photons of a fourth wavelength to a fourth photosensitive region, the four photosensitive region defining a fourth collection area larger than the first collection area. The first wavelength may correspond to red, the second wavelength may correspond to blue, the third wavelength may correspond to green, and the fourth may wavelength correspond to infrared.

In the example method, each image pixel may define a long dimension measured parallel to a router collection area of the color router. Routing photons of the first wavelength may further comprise horizontally routing the photons of the first wavelength no more than three-quarters of the long dimension to reach the first photosensitive region. Routing photons of the second wavelength may further comprise horizontally routing the photons of the second wavelength no more than three-quarters of the long dimension to reach the second photosensitive region. Routing photons of the third wavelength further comprises horizontally routing the photons of the third wavelength no more than three-quarters of the long dimension to reach the third photosensitive region.

In the example method: the color router may define a first quadrant and a second quadrant: the first photosensitive region may define a composite collection area made up of a plurality of discrete photosensitive regions; and the plurality of discrete photosensitive regions may be are equally divided beneath the first quadrant and the second quadrant. The color router may be further configured to route photons of the first wavelength that arrive within the first quadrant to discrete photosensitive regions directly beneath the first quadrant, and to route photons of the first wavelength that arrive within the second quadrant to discrete photosensitive regions directly beneath the second quadrant. The example method may further comprise: detecting a phase imbalance based on a different number of photons arriving in the first quadrant compared to the second quadrant; and modifying a focus parameter based on the phase difference.

The example method may further comprise collimating photons between the scene and the color router.

### BRIEF DESCRIPTION OF THE DRAWINGS

For a detailed description of example embodiments, reference will now be made to the accompanying drawings in which:

FIG. 1A shows an imaging system in accordance with at least some embodiments;

FIG. 1B shows an implementation of an imaging system, in accordance with at least some embodiments;

FIG. 2 shows an image sensor in accordance with at least some embodiments;

FIG. 3A shows an overhead view of a related-art image pixel;

FIG. 3B shows a cross-sectional view of a related-art image pixel;

FIG. 4 shows a perspective, exploded view of an image pixel in accordance with at least some embodiments;

FIG. 5 shows an overhead view and shorthand notation of the example image pixel of FIG. 4 with RYGB sensitivity, in accordance with at least some embodiments;

FIG. 6 shows an overhead view an example image pixel with RYGB sensitivity, in accordance with at least some embodiments;

FIG. 7 shows an overhead view of an image pixel in accordance with at least some embodiments;

FIG. 8 shows an overhead view of an image pixel in accordance with at least some embodiments;

FIG. 9 shows an overhead view of an image pixel in accordance with at least some embodiments;

FIG. 10 shows an overhead view of an image pixel in accordance with at least some embodiments;

FIG. 11 shows an overhead view of an image pixel in accordance with at least some embodiments;

FIG. 12 shows an overhead view of an image pixel in accordance with at least some embodiments;

FIG. 13 shows an overhead view of an image pixel in accordance with at least some embodiments;

FIG. 14 shows an overhead view of an image pixel in accordance with at least some embodiments;

FIG. 15 shows an overhead view of an image pixel in accordance with at least some embodiments;

FIG. 16 shows an overhead view of an image pixel in accordance with at least some embodiments;

FIG. 17 shows a cross-sectional view of an image pixel including a collimator in accordance with at least some embodiments;

FIG. 18 shows a cross-sectional view of an image pixel including a collimator in accordance with at least some embodiments;

FIG. 19 shows an exploded side-elevation view of a color router in accordance with at least some embodiments; and

FIG. 20 shows an exploded side-elevation view of a color router in accordance with at least some embodiments.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections.

Terms defining an elevation, such as “above,” “below,” “upper”, and “lower” shall be locational terms in reference to a direction of light incident upon a pixel array and/or an image pixel. Light entering shall be considered to interact with or pass objects and/or structures that are “above” and “upper” before interacting with or passing objects and/or structures that are “below” or “lower.” Thus, the locational terms may not have any relationship to the direction of the force of gravity.

“IR” shall mean infrared.

In relation to electrical devices, whether stand alone or as part of an integrated circuit, the terms “input” and “output” refer to electrical connections to the electrical devices, and shall not be read as verbs requiring action. For example, a differential amplifier, such as an operational amplifier, may have a first differential input and a second differential input, and these “inputs” define electrical connections to the operational amplifier, and shall not be read to require inputting signals to the operational amplifier.

“Controller” shall mean, alone or in combination, individual circuit components, an application specific integrated circuit (ASIC), a microcontroller with controlling software, a reduced-instruction-set computing (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art understands that the following description has broad application, and the discussion of any embodiment is meant only to be exemplary of that embodiment, and not intended to intimate that the scope of the disclosure, including the claims, is limited to that embodiment.

Various examples are directed to imaging systems, image pixels, and related methods. More particularly, at least some examples are directed to image pixels designed and constructed to be more sensitive in low-light situations by not using color filters, which color filters tend to absorb light of certain frequencies and thus reduce the overall number of photons available to the photosensitive regions. More particularly, various examples are directed to image pixels that use color routers to direct photons of light, incident upon a collection area of the color router, to the underlying photosensitive regions. The routing is based on the wavelength of each photon. Other examples are directed to image pixels in which each photosensitive region has a collection area associated with an overlying color router, and where the collection area of each photosensitive region is proportional to the wavelength of photons directed to each photosensitive region. That is, photons having shorter wavelengths such blue are directed to photosensitive regions with smaller collection areas, and photons having longer wavelengths such as red or infrared are directed to photo sensitive regions with larger collection areas. In yet still other examples, the underlying photosensitive regions are arranged such that the longest horizontal distance a photon travels through a color router is half the long dimension of the image pixel. The specification now turns to example systems to orient the reader.

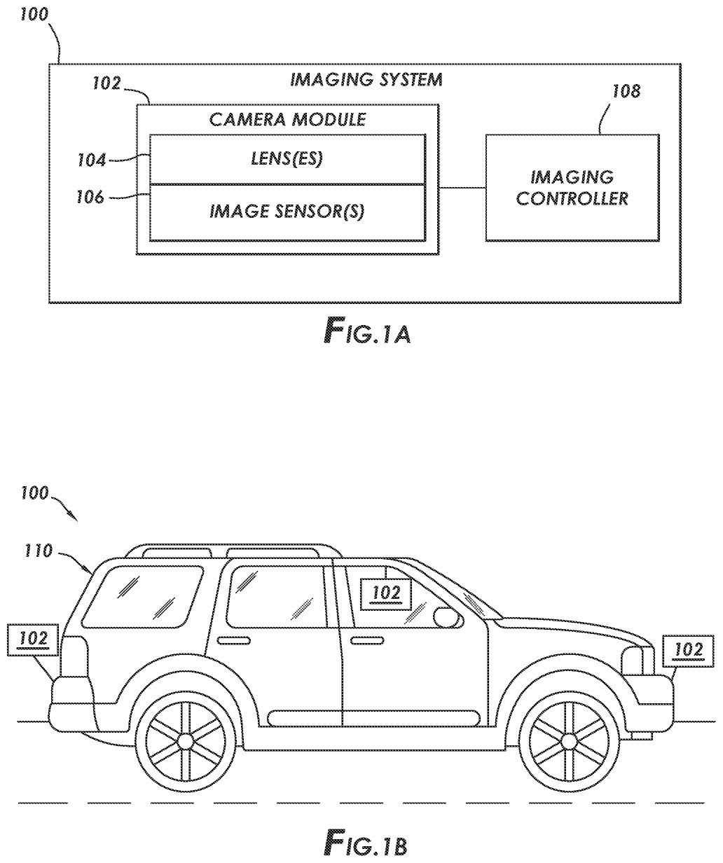

FIG. 1A shows an example imaging system. In particular, the example imaging system 100 may be a portable electronic device such as a camera, a cellular telephone, a tablet computer, a webcam, a video camera, a video surveillance system, or a video gaming system with imaging capabilities. In other cases, the imaging system 100 may be an automotive imaging system. Camera module 102 may be used to convert incoming light into digital image data. Camera module 102 may include one or more lens system, hereafter just lenses 104, and one or more corresponding image sensors 106. Lenses 104 may include fixed and/or adjustable lenses. During image capture operations, light from a scene may be focused onto image sensor 106 by lenses 104. In the case of adjustable lenses, various focus parameters may be adjustable by the camera module 102 and/or the imaging controller 108. Image sensor 106 may comprise circuitry for converting analog pixel data into corresponding digital image data to be provided to the imaging controller 108. If desired, camera module 102 may be provided with an array of lenses 104 and an array of corresponding image sensors 106.

The imaging controller 108 may include one or more integrated circuits, such as image processing circuits, microprocessors, and storage devices such as random-access memory and non-volatile memory. The imaging controller 108 may be implemented using components that are separate from camera module 102 or that form part of camera module 102, such as circuits that form part of the image sensor 106. Digital image data captured by the camera module 102 may be processed and stored using the imaging controller 108. Processed image data may, if desired, be provided to external equipment, such as a computer, an external display, or other devices, using wired and/or wireless communications paths coupled to imaging controller 108.

FIG. 1B shows an example imaging system. In particular, the example imaging system 100 comprises an automobile or vehicle 110. Vehicle 110 is illustratively shown as a passenger vehicle, but the example imaging systems 100 may be any type of vehicle, including commercial vehicles, busses, tractor-trailer vehicles, on-road vehicles, off-road vehicles, tractors, and crop harvesting equipment. In the example of FIG. 1B, the vehicle 110 includes a forward-looking cameral module 102 arranged to capture images of scenes in front of the vehicle 110. Such forward-looking camera module 102 can be used for any suitable purpose, such as lane-keeping assist, collision warning systems, distance-pacing cruise-control systems, autonomous driving systems, and proximity detection. The example vehicle 100 further comprises a backward-looking camera module 102 arranged to capture images of scenes behind the vehicle 110. Such backward-looking camera module 102 can be used for any suitable purpose, such as collision warning systems, reverse direction video, autonomous driving systems, monitoring position of overtaking vehicles, backing up, and proximity detection. The example vehicle 110 further comprises a side-looking camera module 102 arranged to capture images of scenes beside the vehicle 110. Such side-looking camera module can be used for any suitable purpose, such as blind-spot monitoring, collision warning systems, autonomous driving systems, monitoring position of overtaking vehicles, lane-change detection, and proximity detection. In situations in which the imaging system 100 is a vehicle, the imaging controller 108 may be a controller of the vehicle 110. The discussion now turns in greater detail to the example image sensor 106 of the camera module 102.

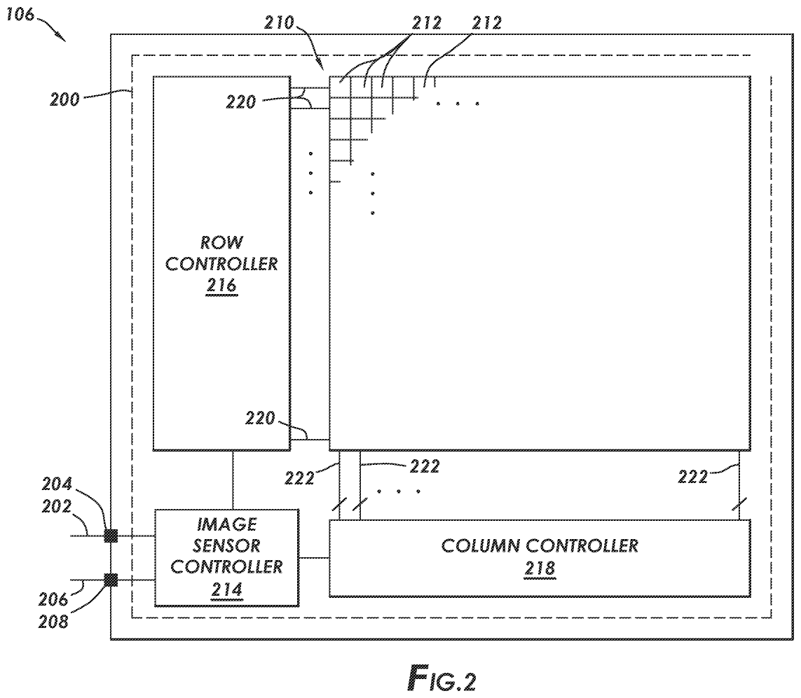

FIG. 2 shows an example image sensor 106. In particular, FIG. 2 shows that the image sensor 106 may comprise a substrate 200 of semiconductor material, such as silicon, encapsulated within packaging to create a packaged semiconductor device or packaged semiconductor product. Bond pads or other connection points of the substrate 200 couple to terminals of the image sensor 106, such as serial communication channel 202 coupled to terminal(s) 204, and capture input 206 coupled to terminal 208. Additional terminals will be present, such as a ground or common terminals, and a power terminal, but the additional terminals are omitted so as not to unduly complicate the figure. While a single substrate 200 is shown, in other cases multiple substrates may be combined to form the image sensor 106 to form a multi-chip module.

The image sensor 106 comprises a pixel array 210 containing a plurality of image pixels 212 arranged in rows and columns. Pixel array 210 may comprise, for example, hundreds or thousands of rows and columns of image pixels 212. Control and readout of the pixel array 210 may be implemented by an image sensor controller 214 coupled to a row controller 216 and a column controller 218. The example row controller 216 may receive row addresses from image sensor controller 214 and supply corresponding row control signals to the image pixels 212, such as reset, row-select, charge transfer, dual conversion gain, and readout control signals. The row control signals may be communicated over one or more conductors, such as row control paths 220.

Column controller 218 may be coupled to the pixel array 210 by way of one or more conductors, such as column lines 222. The column controller may sometimes be referred to as a column control circuit, a readout circuit, and/or column decoder. Column lines 222 may be used for reading out image signals from image pixels 212 and for supplying bias currents and/or bias voltages to the image pixels 212. If desired, during pixel readout operations, a pixel row in the pixel array 210 may be selected using row controller 216 and image signals generated by image pixels 212 in that row can be read out along the column lines 222. Each image pixel 212 may comprises a plurality of photosensitive regions, such as four, nine, or sixteen, and thus while each column line 222 is shown as a single conductor, a plurality of such column lines may be associated with each image pixel 212 in a column.

The example column controller 218 may include sample-and-hold circuitry for sampling and temporarily storing image signals read out from pixel array 210, amplifier circuitry, analog-to-digital conversion (ADC) circuitry, bias circuitry, column memory, latch circuitry for selectively enabling or disabling the column circuitry, or other circuitry that is coupled to one or more columns of pixels in the pixel array 210 for operating the image pixels 212 and for reading out image signals from the image pixels 212. ADC circuitry in the column controller 218 may convert analog pixel values received from the pixel array 210 into corresponding digital image data. Column controller 218 may supply digital image data to the image sensor controller 214 and/or the imaging controller 108 (FIG. 1) over, for example, the serial communication channel 202.

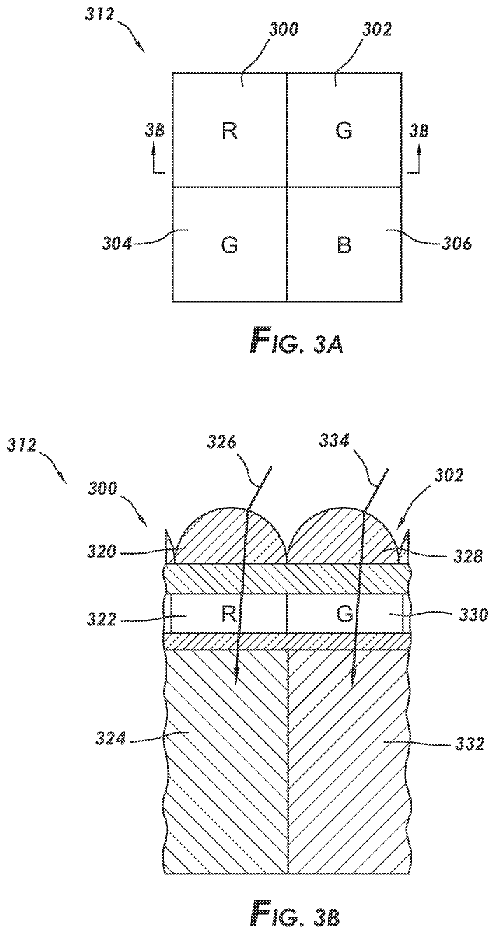

FIG. 3A shows an overhead view of a related-art image pixel 312. In particular, the related-art image pixel 312 includes four total photosensitive regions: a red region 300; a first green region 302; a second green region 304, and a blue region 306. FIG. 3B shows a partial cross-sectional view of the related-art image pixel 312 taken line 3B-3B of FIG. 3A. In particular, FIG. 3B shows that the red sensor is made up of a microlens 320, a red color filter 322, and a photosensitive region 324. Consider, for purposes of discussion, incoming light 326 (illustrated by the arrow) entering the red sensor 300. The light 326 initially encounters the microlens 320, which may be a convex lens designed and constructed to direct the incoming light 326 into the lower regions of the sensor. The lens may be spherical. The light 326 then encounters an optical filter being the red color filter 322. The material of the red color filter 322 is selected to pass light having wavelengths corresponding to red, such as between about 595 and 655 nanometers (nm), and to filter or absorb light of other colors. The remaining light 326 then passes through one more oxide layers (not numbered), and then the remaining light passes into the photosensitive region 324 where the light is absorbed. The absorption of the light produces a corresponding electrical signal having a parameter indicative of the intensity of the red light received, such as the number of photons received during the detection period. The parameter indicative of the intensity may be any suitable parameter, such as amplitude of the current or magnitude amplitude of the voltage. Thus, the red sensor 300 produces an electrical signal proportional the amount of light that finds its way into the photosensitive region 324.

Similarly, FIG. 3B shows that the green sensor 302 is made up of a microlens 328, a green color filter 330, and a photosensitive region 332. Consider, for purposes of discussion, incoming light 334 as illustrated by the arrow entering the green sensor 302. The incoming light 334 initially encounters the microlens 328. The light 334 then encounters an optical filter being a green color filter 330. The material of the green color filter 330 is selected to pass light having wavelengths corresponding to green, such as between about 515 and 575 nm, and to filter or absorb light of other colors. The remaining light 334 then passes through one more oxide layers (not numbered), and then the remaining light passes into the photosensitive region 332 where the light is absorbed. The absorption of the light produces a corresponding electrical signal having a parameter indicative of the intensity of the green light received, such as the number of photons received during the detection period. Again, the parameter indicative of the intensity may be any suitable parameter, such as amplitude of the current or magnitude amplitude of the voltage. Thus, the green sensor 302 produces an electrical signal proportional the amount of light that finds its way into the photosensitive region 332. A similar discussion regarding the second green sensor 304 and the blue sensor 306, each of which may be configured in a same or similar manner, is omitted so as not to unduly lengthen the specification.

Referring to FIGS. 3A and 3B simultaneously. Performance of the related art image pixel 312 may suffer in low-light situations. The overall image pixel 312 defines a light collection area in the form of the four sensors. If each sensor is said to define a square unit area, the example image pixel 312 defines a four square unit area for collection of light. However, because of the use of color filters, which absorb light having wavelengths outside the designed pass band, only a fraction of the light of a particular color incident upon the overall image pixel 312 finds its way into the photosensitive region associated with that color. For example, light having a wavelength corresponding to red but incident upon the green sensors 302 or 304, or incident upon the blue sensor 306, is absorbed by the respective filters, and such absorbed light cannot then contribute to the creation of electrical signals in the photosensitive regions. For the example image pixel 312, only 25% of the red light incident on the overall image pixel 312 finds its way to the photosensitive region associated with the red sensor, only 25% of the blue light incident on the overall image pixel 312 finds its way to the photosensitive region associated with the blue sensor 306, and only 50% of the green light incident on the overall image pixel 312 finds its way to the photosensitive regions associated with the green sensors 302 and 304.

Another reason for poor performance in low-light situations is that the color filters are not themselves perfectly efficient in passing the colors within the passband. For example, the green color filter 330 may be made of material that passes only 90% of the green light incident upon the filter, and it follows the green color filter 330 absorbs about 10% of the green light. Thus, of the green light that falls on overall image pixel 312, only 50% falls on the two example green sensors 302 and 304, and only 90% of the 50%, or only about 45%, of the green light finds its way into the photosensitive regions of the green sensors 302 and 304. The color filters of the red sensor 300 and the blue sensor may have similar issues.

The performance of image sensors may be improved by use of nanophotonic structures or color routers. In particular, a color router is a semiconductor structure that accepts photons incident on upper surface or router collection area defined by the upper surface. The color router then routes photons from the router collection area to the underlying photosensitive regions, with the routing based on the wavelength of each particular photon. The router collection area may correspond to an overall image pixel, thereby being greater in area than an area above a single photosensitive region. The specification hereby defines and adopts the following notation for referencing color represented by the wavelength of a photon: red photons are photons having a wavelength that correspond to the color red; yellow photons are photons having a wavelength that correspond to the color yellow; blue photons are photons having a wavelength that correspond to the color blue; cyan photons are photons having a wavelength that correspond to the color cyan; infrared photons are photons having a wavelength that correspond to infrared; and so on. Consider, as an example, a red-yellow-yellow-cyan (RYYCy) image pixel. With that nomenclature in mind, of all the photons that are incident on the router collection area of the color router of an example RYYCy image pixel: red photons are directed to the photosensitive region designated for receiving red; yellow photons are directed the photosensitive regions designated for receiving yellow; and cyan photons directed to the photosensitive region designated for receiving cyan. Thus, for example, red photons that happen to arrive physically above the photosensitive region designated for cyan or the photosensitive regions designated for yellow are not lost to absorption, but are routed to the photosensitive region designated for red.

FIG. 4 shows an exploded perspective view of an example image pixel 212. In particular, FIG. 4 shows an example image pixel 212 that defines a color router 400 and four photodiodes or photosensitive regions 402, 404, 406, and 408. In the exploded view of FIG. 4, the color router 400 is separated from the photosensitive regions 402, 404, 406, and 408 for purposes of explanation. However, in practice the color router 400 may be above and abut the upper surface of the photosensitive regions 402, 404, 406, and 408 directly, or there may be one or more additional layers between the lower surface of the color router 400 and the upper surface of the photosensitive regions 402, 404, 406, and 408. For example, there may be an oxide layer between the lower surface of the color router 400 and the upper surface of the photosensitive regions 402, 404, 406, and 408. The oxide layer may also include a metallic grid for purposes of draining unwanted electrical current, such as electrostatic charge. The intervening layers between the lower surface of the color router 400 and the upper surface of the photosensitive regions 402, 404, 406, and 408 are not shown so as not to unduly complicate the figure.

The photosensitive regions 402, 404, 406, and 408 are semiconductor regions, such as silicon, within which photons of light may be captured or absorbed to create electrical signals, such as voltage or current. The photosensitive regions 402, 404, 406, and 408 themselves are agnostic the wavelength of the photons absorbed—photons of any suitable wavelength for image pixels, spanning from visible region into the infrared region—may be absorbed once the photons find their way into the semiconductor material. In many cases, each photosensitive region is designed and constructed as photodiode that produces electrical voltage and current responsive to capture or absorption of photons of light.

The example color router 400 defines a router collection area 410 on an upper surface thereof. That is, the upper surface of the color router 400 defines a length L_{CR} and a width W_{CR}, and the length L_{CR} and a width W_{CR} considered together define the collection area. Each photosensitive region 402, 404, 406, and 408 itself defines a collection aperture or collection area. For example, photosensitive region 408 defines a length L_{PD} and a width W_{PD}, and the length L_{PD} and the width W_{PD} considered together define a collection area. Thus, the photosensitive region 402 defines a collection area 412, the photosensitive region 404 defines a collection area 414, the photosensitive region 406 defines a collection area 416, and the photosensitive region 408 defines a collection area 418. Given that the photosensitive regions 402, 404, 406, and 408 reside in the area beneath the color router 400 or coextensive with the color router 400, the collection area for each photosensitive region is smaller than the router collection area 410. In other examples, the router collection area 410 may be coextensive with more or fewer photosensitive collection areas than what is shown in FIG. 4. Different arrangements, sizes, shapes, sensitivities, and/or other characteristics of the photosensitive regions underneath the color router 400 may be used in place of the arrangement and characteristics shown in FIG. 4, some of which will be discussed further herein.

In various examples, photons of light that are incident upon the router collection area 410 of the color router 400 enter the structure of the color router 400 and are routed to particular the collection areas of the underlying photosensitive regions. In an image pixel 212 having four underlying photosensitive regions, the color router 400 may be designed and constructed to: route photons of a first wavelength received at the router collection area 410 to the photosensitive region 402; route photons of a second wavelength received at the router collection area 410 to the second photosensitive region 404; route photons of a third wavelength received at the router collection area 410 to the photosensitive region 406; and route photons of a fourth wavelength received at the router collection area 410 to the photosensitive region 408. The representative example of FIG. 4 is an image pixel 212 having red, yellow, green, and blue (RYGB) sensitivity. Thus, for the example RYGB sensitivity, the color router 400 may be designed and constructed to: route red photons to the photosensitive region 402; route yellow photons to the photosensitive region 404; route green photons to the photosensitive region 406; and route blue photons to the photosensitive region 408.

The example image pixel 212 with the RYGB sensitivity may be particularly suited for automotive applications. That is, one of the more difficult tasks performed by automated driving system systems is distinguishing between red and yellow, for example, the red and yellow of a stop light. The wavelengths corresponding to red and the wavelengths corresponding to yellow are close together. Related art image pixels using color filters not only suffer the collection-area shortcomings noted above, but yellow color filters designed to pass yellow photons tend absorb a high percentage of the desirable photons given the yellow wavelength proximity to red. However, using a color router 400 reduces the collection-area shortcomings—yellow photons incident anywhere on the router collection area 410 may be routed to the underlying photosensitive region 404. And with no yellow color filter needed, the percentage of yellow photons that find their way into the photosensitive region 404 is significantly higher than for related-art image pixels using color filters. Of course, the statement regarding yellow is true for all the color sensitivity of the image pixel 212.

The color router 400 may take any suitable form. In many cases, the color router 400 is constructed of several levels or layers, where each layer is designed and constructed to perform at least a partial routing. Each layer may be designed and constructed of a plurality of three-dimensional structures, such as cuboids of materials having varying indices of refraction and/or different sizes. For example, the three-dimensional structures a particular layer may be selectively made of silicon dioxide and silicon nitride to bend and reflect photons at least partially toward to the designated underlying photosensitive region. For the example image pixel 212 of FIG. 4 having RYGB sensitivity, it may be that there are several different designs for the color router 400 that work equivalently.

The design of the color router 400 may not be 100% percent efficient at routing photons received at the router collection area 410 to the corresponding color collection areas 412, 414, 416, and 418. For example, some photons may be reflected back out through router collection area 410. Other photons may be misrouted, such as photons with a high angle of incidence. Moreover, refractions and reflections within the color router 400 may send photons streaming out between the router collection area 410 and the various collection areas 412, 414, 416, and 418. However, even taking into account the potential inefficiencies of such a color router, the overall image pixel 212 may still have better collection efficiency, and thus better low-light sensitivity, than other image pixels using color filters. Consider, as an example, that the color router 400 is only 50% efficient in routing red photons. That is, in the example only half the red photons incident upon the router collection area 410 find their way to the photosensitive region 406. The 50% assumed efficiency is still likely higher than the efficiency of the color-filtered image pixel's collection of red photons over only 25% of the same region. Further, given that a red color filter may only pass about 90% of the red photons, an example image pixel with a color router 400 having only 50% efficiency in routing red photons may potentially collect more than double the number of photons of the related-art image pixel 312 with a red color filter 322.

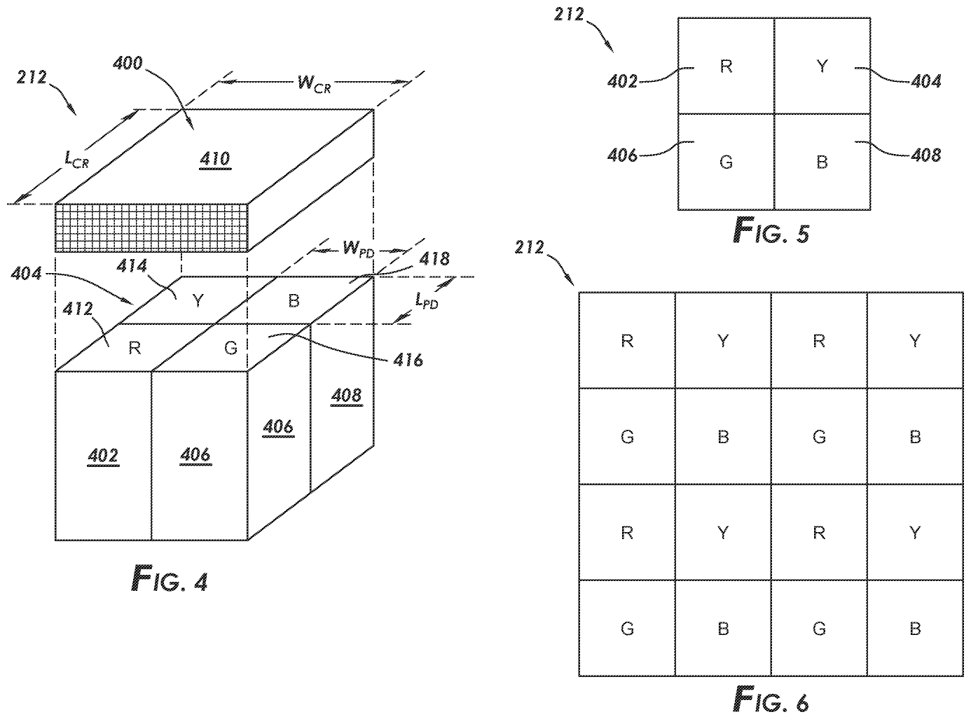

FIG. 5 shows an overhead view, and shorthand notation for, the example image pixel 212 of FIG. 4 with RYGB sensitivity. In particular, the color router 400 is not visible in FIG. 5, but FIG. 5 does show the photosensitive region 402 designated to receive red photons, the photosensitive region 404 designated to receive yellow photons, the photosensitive region 406 designated to receive green photons, and the photosensitive region 408 designated to receive blue photons. In some cases, each image pixel 212 may contain only the four photosensitive regions. However, in other cases the layout of FIG. 5 may be considered a unit cell within the overall image pixel, and the image pixel may duplicate the unit cell and its color router several times within an image pixel. FIG. 6 shows an example image pixel 212 with RYGB sensitivity, and in which the example unit cell duplicated four times to create the overall image pixel 212 having sixteen total photosensitive regions.

Again, the example image pixel 212 may be particularly suited for automotive applications. However, use of an image pixel with both red and yellow sensitivity, along with a color router, is not limited to just RYGB sensitivity. FIG. 7 shows an overhead view of another example image pixel 212 in the shorthand notation, the image pixel designed for RYYB sensitivity. In particular, the example image pixel 212 defines the photosensitive region 402 designated to receive red photons, the photosensitive region 404 designated to receive yellow photons, the photosensitive region 406 also designated to receive yellow photons, and the photosensitive region 408 designated to receive blue photons. As before, the image pixel 212 may contain only the four photosensitive regions, or the four photosensitive regions may be considered unit cell within the overall image pixel and duplicated, such as four total unit cells or sixteen total photosensitive regions.

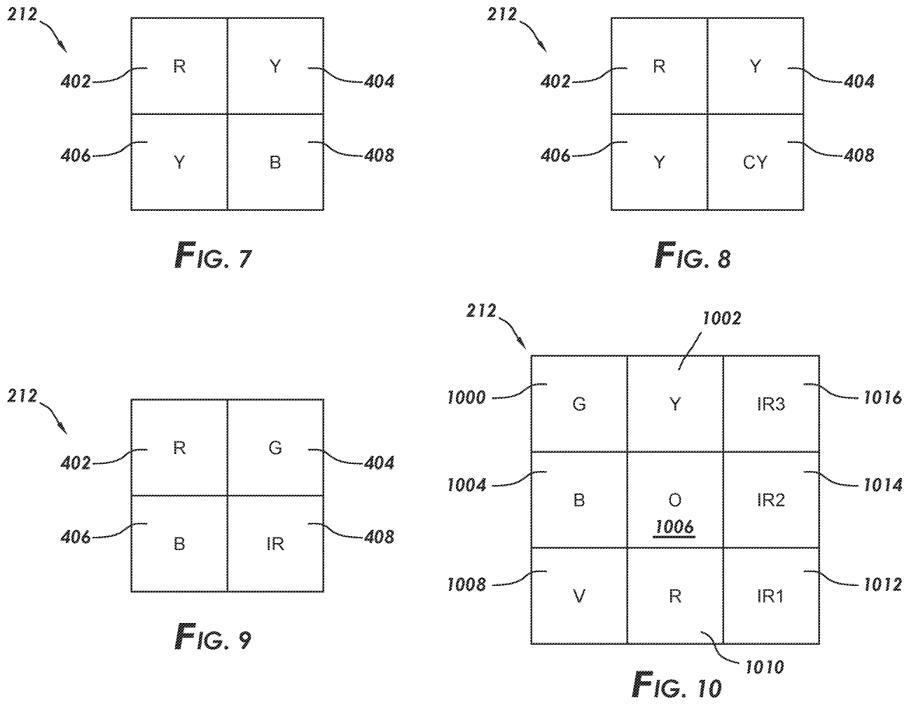

FIG. 8 shows an overhead view of yet another example image pixel 212 in the shorthand form, the image pixel designed for red-yellow-yellow-cyan (RYYCy) sensitivity. In particular, the example image pixel 212 defines the photosensitive region 402 designated to receive red photons, the photosensitive region 404 designated to receive yellow photons, the photosensitive region 406 also designated to receive yellow photons, and the photosensitive region 408 designated to receive cyan photons. As before, the image pixel 212 may contain only the four photosensitive regions, or the four photosensitive regions may be considered unit cell within the overall image pixel and duplicated, such as four total unit cells or sixteen total photosensitive regions.

The various specific embodiments discussed to this point have been directed to automotive applications concerned with the visible spectrum; however, use of the color router may also be beneficial when the image pixel is designed and constructed to receive infrared wavelengths. FIG. 9 shows an overhead view of an example image pixel 212 in the shorthand notation, the image pixel designed for RGB-infrared (RGB-IR) sensitivity. In particular, the example image pixel 212 defines the photosensitive region 402 designated to receive red photons, the photosensitive region 404 designated to receive green photons, the photosensitive region 406 designated to receive blue photons, and the photosensitive region 408 designated to receive infrared photons, such as above 700 nm, or above about 850 nm, or above about 905, or above about 940 nm. As before, the image pixel 212 may contain only the four photosensitive regions, or the four photosensitive regions may be considered unit cell within the overall image pixel and duplicated, such as total unit cells or sixteen total photosensitive regions.

In yet still further cases, the image pixels may be designed and constructed for hyperspectral use. Hyperspectral imaging may be used in industrial applications for counterfeit detection, powder analysis, and/or checking the integrity of packaging. In agriculture, hyperspectral imaging may be used to precisely water, fertilize, weed and pest control. There may be applications of hyperspectral imaging in medical and surveillance as well. FIG. 10 shows an overhead view of an example image pixel 212 in the shorthand notation, the image pixel designed for hyperspectral applications. In particular, the example image pixel 212 of FIG. 10 defines a photosensitive region 1000 designated to receive green photons, a photosensitive region 1002 designated to receive yellow photons, a photosensitive region 1004 designated to receive blue photons, a photosensitive region 1006 designated to receive orange photons, a photosensitive 1008 designated to receive violet photons having wavelengths corresponding to violet, and a photosensitive region 1010 designated to receive red photons. In addition to the visible regions, the example image pixel 212 of FIG. 10 includes a photosensitive region 1012 designated to receive a first range of infrared photons, a photosensitive region 1014 designated to receive a second range of infrared photons, and a photosensitive region 1016 designated to receive a third range of infrared photons.

Still referring to FIG. 10, in some cases each image pixel 212 may contain only the nine photosensitive regions. However, in other cases the layout of FIG. 10 may be considered a unit cell within the overall image pixel, and the image pixel may duplicate the unit cell (including its color router) several times within an image pixel. If the unit cell is FIG. 10 duplicated four times, the overall image pixel 212 may have 36 total photosensitive regions.

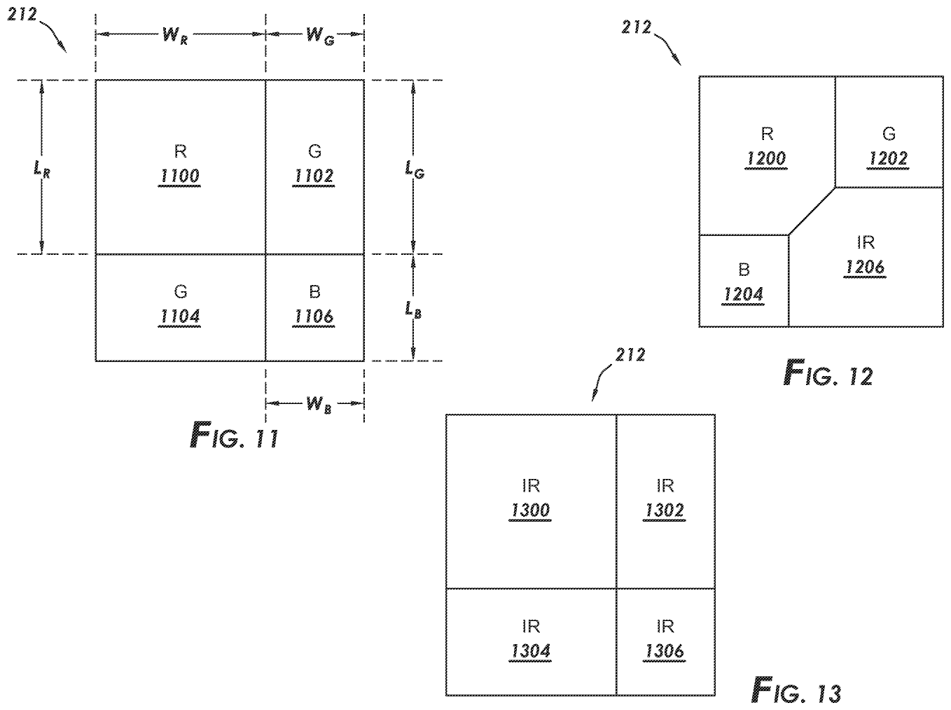

FIGS. 11-13 show example image pixel layouts. These layouts are designed based at least in part on routing considerations of the color router and capture considerations of the photosensitive regions. For example, the ability of a color router to route photons incident upon the router collection area to an underlying photosensitive region may depend on the wavelength of the photon and the distance the photons travel within the color router, largely the horizontal distance. In addition, a photosensitive region's ability to capture or absorb a photon may be related to the wavelength of the photon and the volume of the photosensitive regions. For a specific volume of a photosensitive region, photons having shorter wavelengths, such as purples and blues, are more easily and quickly absorbed than photons having longer wavelengths, such as reds and infrareds.

FIG. 11 shows an overhead view of an example image pixel 212 in the shorthand notation, the image pixel designed to at least partially address the ability of the photosensitive regions to capture or absorb photons based on the wavelength and the color router's ability to route photons based on wavelength. In particular, the example image pixel 212 of FIG. 10 defines a photosensitive region 1100 designated to receive red photons, a photosensitive region 1102 designated to receive green photons, a photosensitive region 1104 also designated to receive green photons, and a photosensitive region 1106 designated to receive blue photons. Though not visible in FIG. 11, each photosensitive regions 1100, 1102, 1104, and 1106 has a uniform thickness or depth, with depth measured perpendicular to the plane of the page.

The example photosensitive region 1100 designated for red defines a length LR and a width WR, and together the length LR and the width WR define a collection area for the photosensitive region 1100. Given that the overlaying color router, not shown in the shorthand notation, spans the entire image pixel 212, the collection area for the photosensitive region 1100 is smaller than the router collection area 410 (FIG. 4).

The example photosensitive region 1102 designated for green defines a length L_{G} and a width W_{G}, and together the length L_{G} and the width W_{G} define a collection area for the photosensitive region 1102. The collection area for the photosensitive region 1102 is smaller than the router collection area 410 (FIG. 4). Moreover, the collection area for the photosensitive region 1102 is smaller than the collection area for the photosensitive region 1100. The photosensitive region 1104 also designated for green has a collection area that is about the same size as the collection area for the photosensitive region 1102. The example photosensitive region 1106 designated for blue defines a length L_{B} and a width W_{B}, and together the length L_{B} and the width W_{B} define a collection area for the photosensitive region 1106. The collection area for the photosensitive region 1102 is smaller than the router collection area 410 (FIG. 4). Moreover, the collection area for the photosensitive region 1106 is smaller than the collection areas for the photosensitive regions 1100 and 1102.

Still referring to FIG. 11, consider an example red photon incident upon the router collection area 410. On average, such a red photon may have a horizontal distance to travel to reach the red photosensitive region 1100, the horizontal distance being measured in the plane of the page of FIG. 11. However, given the size of the collection area for the red photosensitive region 1100 is a larger proportion of the color router collection area than the more other pixels, such as those in FIGS. 7-9, the horizontal distance may be shorter to reach the red photosensitive region than for an image pixel having smaller proportion of red photosensitive region to the color router collection area.

Now consider a blue photon incident upon the router collection area 410. On average, such a blue photon may have longer horizontal distance to travel to reach the blue photosensitive region 1106 than the red photon since the blue photosensitive region 1106 is smaller than the red photosensitive region. But because the wavelength of blue is shorter than the wavelength of red, the blue photon it may be more efficiently absorbed by the silicon of the photodiode than the red photon.

In some cases, each image pixel 212 of FIG. 11 may contain only the four photosensitive regions. However, in other cases the layout of FIG. 11 may be considered a unit cell within the overall image pixel, and the image pixel may duplicate the unit cell and its color router several times within an image pixel. If the unit cell is FIG. 11 duplicated four times, the overall image pixel 212 may have sixteen total photosensitive regions.

The size considerations for the collection areas of the photosensitive regions are not limited to just wavelengths in the visible spectrum. The same collection area and wavelength considerations may apply for image pixels with mixed sensitivity, such as including visible and infrared wavelengths. FIG. 12 shows an overhead view of an example image pixel 212 in the shorthand notation, in this case having photosensitive regions for both visible and infrared. In particular, the example image pixel 212 of FIG. 12 defines a photosensitive region 1200 designated to receive red photons, a photosensitive region 1202 designated to receive green photons, a photosensitive region 1204 also designated to receive blue photons, and a photosensitive region 1206 designated to receive infrared photons. As before, and though not visible, each photosensitive region 1200, 1202, 1204, and 1206 has a uniform thickness or depth (the depth measured perpendicular to the plane of the page.)

In the example of FIG. 12, the collection area associated with the photosensitive region 1206 designated for infrared is larger than the collection area for the photosensitive region 1200 designed for red. The collection area associated with the photosensitive region 1200 designated for red is larger than the collection area for the photosensitive region 1202 designated for green. The collection area associated with the photosensitive region 1202 designated for green is larger than the collection area for the photosensitive region 1202 designated for blue. The size of the collection areas may be based on the wavelength(s) of the light designated to be routed to the respective collection area. In some implementations, the size may be directly proportional to a wavelength of the designated wavelength(s). In some cases, each image pixel 212 of FIG. 12 may contain only the four photosensitive regions. However, in other cases the layout of FIG. 12 may be considered a unit cell within the overall image pixel, and the image pixel may duplicate the unit cell and its color router several times within an image pixel. If the unit cell is FIG. 12 duplicated four times, the overall image pixel 212 may have sixteen total photosensitive regions.

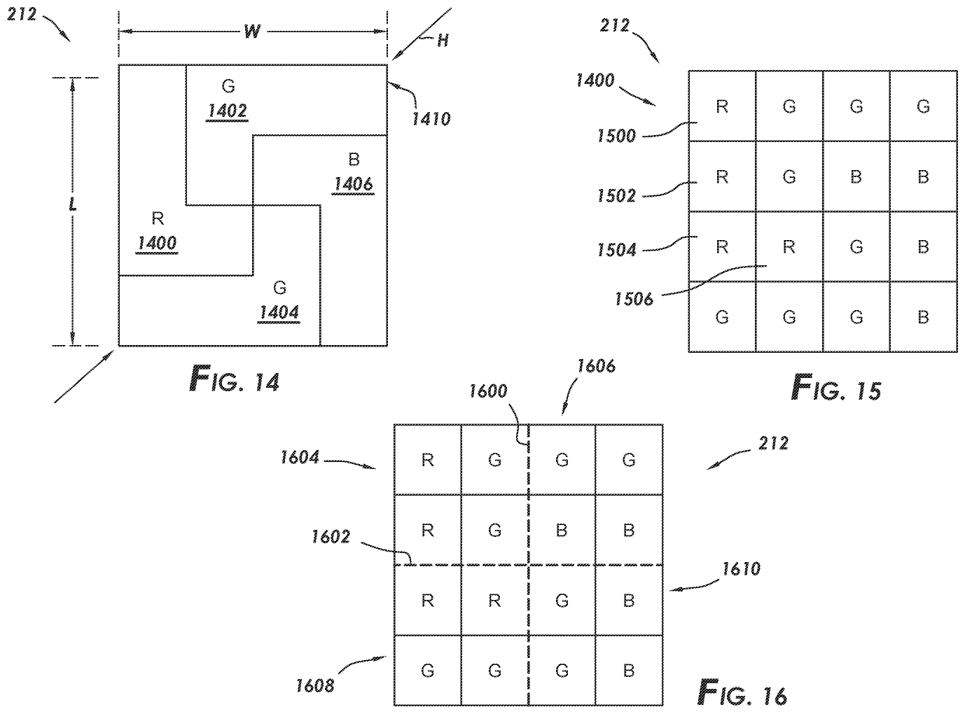

The size considerations for the collection areas of the photosensitive regions are not limited to just wavelengths in the visible spectrum and mixed visible and infrared. The same collection area and wavelength considerations may apply for image pixels dedicated only to infrared. FIG. 13 shows an overhead view of an example image pixel 212 in the shorthand notation, in this case only having photosensitive regions for infrared. In particular, the example image pixel 212 of FIG. 12 defines a photosensitive region 1300 designated to receive a first range of infrared photons, a photosensitive region 1302 designated to receive a second range of infrared photons, a photosensitive region 1304 designated to receive a third range of infrared photons, and a photosensitive region 1306 designated to receive a fourth range of photons. As before, and though not visible, each photosensitive regions 1300, 1302, 1304, and 1306 has a uniform thickness or depth, the depth measured perpendicular to the plane of the page.

In the example of FIG. 13, the collection area associated with the photosensitive region 1300 designated for the first range of infrared is larger than the collection area for the photosensitive region 1302 designed for the second range of infrared. The collection area associated with the photosensitive region 1302 designated for the second range of infrared is larger than the collection area for the photosensitive region 1306 designated for fourth range of infrared. The collection area associated with the photosensitive region 1304 designated for the third range of infrared is larger than the collection area for the photosensitive region 1306 designated for the fourth range of infrared. In this example, the first range of infrared may have longer wavelengths than the second range of infrared; the second range of infrared may have longer wavelengths than the third range of infrared; and the third range of infrared may have longer wavelengths than the fourth range of infrared. In some cases, each image pixel 212 of FIG. 12 may contain only the four photosensitive regions. However, in other cases the layout of FIG. 12 may be considered a unit cell within the overall image pixel, and the image pixel may duplicate the unit cell (including its color router) several times within an image pixel. If the unit cell is FIG. 12 duplicated four times, the overall image pixel 212 may have sixteen total photosensitive regions.

In the examples described above, each photosensitive region defines a cuboid with a square collection aperture or collection area, such as FIGS. 4-10 and 13, or a substantially square collection area, such as FIG. 12. The sizes of the collection areas may be in part based on the volumes of the respective photosensitive regions, and the sizes also may aid the routing of the color router, with larger target area for longer wavelengths. In other implementations, the layout of the photosensitive regions for a particular wavelength range may be different shapes. In addition, the shape of individual collection area may be selected to aid the routing of photons by the color router. The shape of each unit may be selected irrespective of the designated wavelengths of photons for the given photosensitive region.

In some examples, multiple discrete photosensitive regions may be arranged together to create the desired shape for the given wavelength range. It follows that the collection areas for the multiple discrete photosensitive regions considered together define the overall collection for the given wavelength range. The detected signal for the given wavelength range may be realized by summing the signals generated by the discrete photosensitive regions in the analog or digital domain. For example, in FIG. 13, the photosensitive region 1306 may be single discrete photosensitive region being an example of standard size or unit-size photosensitive region. The overall photosensitive region 1302 may be created by using two discrete photosensitive regions of the unit-size. The overall photosensitive region 1304 may likewise be created by using two discrete photosensitive regions of the unit-size. The overall photosensitive region 1300 may be created by using four discrete photosensitive regions of the unit-size. The process integration may be simpler by implementing unit-size photosensitive regions.

FIG. 14 shows an overhead view of an example image pixel 212 in the shorthand notation, the image pixel designed to at least partially address the color router's ability to route photons based on wavelength. In particular, the example image pixel 212 of FIG. 14 defines a photosensitive region 1400 designated to receive red photons, a photosensitive region 1402 designated to receive green photons, a photosensitive region 1404 also designated to receive green photons, and a photosensitive region 1406 designated to receive blue photons. The example image pixel 212 defines a length L, a width W, and a longest dimension H being the hypotenuse of a triangle defined by the length L and width W.

The example photosensitive region 1400 designated for red defines a collection area with a first shape. In the example of FIG. 14, the shape is an L-shape with the long section defining portion of a first border of the image pixel 212, and the short section extending toward the center of the image pixel 212. The L-shape of the has a width defined by a short dimension. The example photosensitive region 1402 designated for green defines an L-shape with the long section defining a portion of a second border of the image pixel, and the short section extending toward the center of the image pixel. The long section of the photosensitive region 1402 and the short dimension of the long section of photosensitive region 1400 define the second border of the image pixel 212. The example photosensitive region 1406 designated for blue defines an L-shape with the long section defining a portion of a third border of the image pixel 212, and the short section extending toward the center of the image pixel 212. The long section of the photosensitive region 1406 and the short dimension of the long section of photosensitive region 1402 defined the third border of the image pixel 212. The example photosensitive region 1404 designated for green defines an L-shape with the long section defining a portion of a fourth border of the image pixel 212, and the short section extending toward the center of the image pixel 212. The long section of the photosensitive region 1404 and the short dimension of the long section of the photosensitive region 1406 define the fourth border of the image pixel 212. And finally, the long section of the photosensitive region 1400 and the short dimension of the long section of the photosensitive region 1404 define the first border of the image pixel 212.

Still referring to FIG. 14, consider an example red photon incident upon the router collection area 410. On average, such a red photon has a horizontal distance to travel to reach the red photosensitive regions 1400, the horizontal distance being measured in the plane of the page of FIG. 14. However, given the shape of the collection area for the red photosensitive region 1400, the color router 400 (FIG. 4) may have an easier time routing such a photon as the longest horizontal distance such a red photon may travel within the color router 400 is half the long dimension of the image pixel 212. For the example red photon, consider that the red photon enters the color router 400 at a location 1410 at the upper right corner of the image pixel 212 in the view of FIG. 14, that is, at the outermost point of the long section of the L-shaped photosensitive regions 1402. Thus, the example red photon need only be routed a distance being half the longest dimension of the image pixel, here the half the hypotenuse H. The same description applies for longest horizontal travel distance for blue photons. For green photons, the shortest travel distance is one-quarter of the length or width (for a square image pixel). Such a layout may thus make easier routing of the photons by the color router 400, and thus may make the design of the color router simpler. Other shaped layouts are possible, and other color sensitivities are possible, such as RYYCy. And as before, the example layout to FIG. 14 may be a unit cell that is itself duplicated several times, such as four times, within the overall image pixel 212.

The example image pixel 212 of FIG. 14 assumes that the photosensitive regions 1400, 1402, 1404, and 1406 are continuous regions within the respective L-shapes. However, in yet still further cases, the underlying photosensitive regions designated to receive a particular wavelength of photon may be a composite collection area made up a plurality of discrete regions. FIG. 15 shows an overhead view of an example image pixel 212 in the shorthand notation, where the image pixel has a plurality of discrete regions that together define the L-shaped photosensitive regions of FIG. 14. In particular, the example L-shaped photosensitive region 1400 is defined by discrete photosensitive regions 1500, 1502, 1504 and 1506. In the example of FIG. 15, each of the discrete photosensitive regions 1500, 1502, 1504 and 1506 defines a collection area that is square, having sides that are the length of the short dimension. However, the collection areas need not be square, so long as in the aggregate the collection areas defined the desired shape—here an L-shape structure. Moreover, while FIG. 15 shows four discrete photosensitive regions, two or more discrete photosensitive regions may together form the example photosensitive region 1400. The example image pixel 212 similarly shows photosensitive regions 1402, 1404, and 1406 made of discrete photosensitive regions, but the description of the discrete makeup of photosensitive regions 1402, 1404, and 1406 is the same as photosensitive region 1400 and will not be repeated so as not to unduly lengthen the specification.

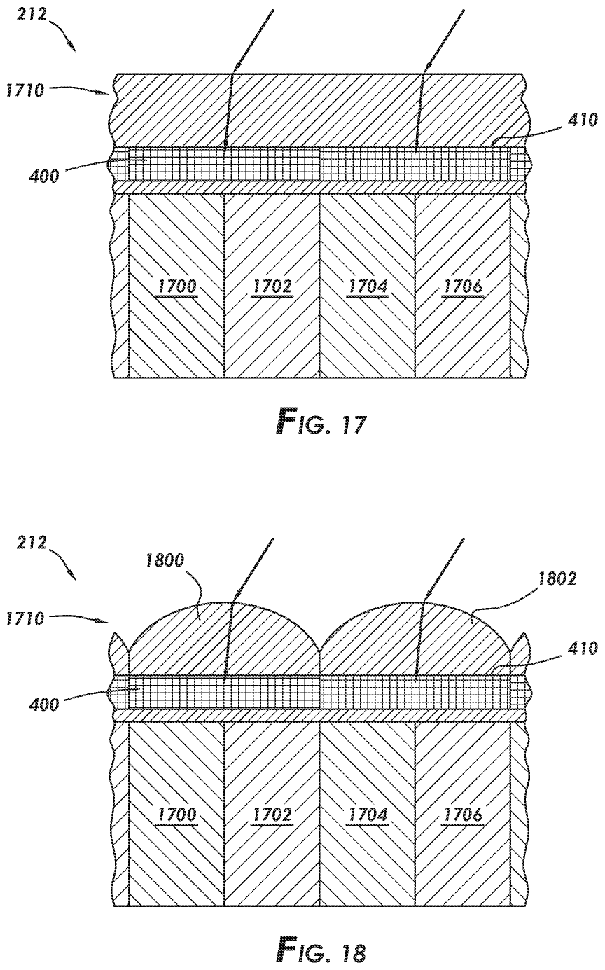

Other considerations for the design of the color router 400 may include phase detection auto focus (PDAF) considerations. That is, the design and construction of the color router 400 may route photons to respective photosensitive regions not only based on wavelength, but also based on the physical location of the router collection area at which a photon enters the color router 400. FIG. 16 shows an overhead view of an example image pixel 212 in the shorthand notation, and where the image pixel 212 has the same photosensitive areas shown in FIG. 14 and the same discrete units shown in FIG. 15. Though the color router 400 is not visible in the shorthand notation of FIG. 16, the color router 400 may nevertheless be designed and constructed to route photons of a particular color designated for PDAF based on location of the router collection area at which a photon arrives.

To describe such operation, FIG. 16 includes vertical dashed line 1600 and horizontal dashed line 1602. The example vertical line 1600 and horizontal line 1602 conceptually, though not necessarily physically, divide the collection area of the color router 400, and the underlying photosensitive regions, into four sub-sections; namely quadrants 1604, 1606, 1608, and 1610. In this example, consider that green photons are designated for PDAF to be routed as a function of collection area—though any color may be selected in other implementations. In the example of FIG. 16, the four sub-sections are each composed of equal numbers of discrete photosensitive regions for the designated PDAF color, green. That is, the quadrants 1604, 1606, 1608, and 1620 each include two discreet photosensitive regions designated for green photons. Having two discrete photosensitive regions in each sub-section is merely an example. Each sub-section need only have the same collection area for the designated color as a corresponding sub-section across a dividing line, such as the vertical dashed line or the horizontal dashed line. In addition, the collection area in each sub-section may be defined by a single photosensitive region or a plurality of discrete photosensitive regions.

Using the image pixel 212 in FIG. 16, green photons that arrive at or intersect the router collection area 410 (FIG. 1) within the quadrants 1604 and 1608 are routed to photosensitive regions beneath the quadrants 1604 and 1608, respectively, designated for green. The example green photons that arrive at or intersect the router collection area 410 (FIG. 4) within the quadrants 1606 and 1610 are routed to photosensitive regions directly beneath the quadrants 1606 and 1610 designated for green. Where the image pixel 212 of FIG. 16 is a member of the overall pixel array 210 (FIG. 2), a focus issue may be detected based on an uneven phase or spatial distribution of the example green photons arriving at the image pixel 212. For example, based on the routing described with respect to FIG. 16, the resulting phase or spatial distribution of green photons arriving at the underlying photosensitive regions may be more heavily weighted on one side the vertical dashed line 1600 than the other. The precise phase imbalance may further be determined based on the location of the image pixel 212 within the overall pixel array 210, the orientation of the image pixel 212 to the scene, and/or the extent the scene is out of focus. As a result, by detecting a phase or spatial imbalance across the example vertical dashed line 1600 associated with the image pixel 212 of FIG. 16, the magnitude and location of the phase imbalance may be used to automatically adjust focus of the lens(es) 104 (FIG. 1) of the camera module 102 (FIG. 1).

The same reasoning may be applied with respect to the quadrants shown in FIG. 16 divided by the horizontal dashed line 1602. For example, green photons that arrive at or intersect the router collection area 410 (FIG. 1) within the quadrants 1604 and 1606 are routed to photosensitive regions beneath the quadrants 1604 and 1606, respectively, designated for green. The example green photons that arrive at or intersect the router collection area 410 within the quadrants 1608 and 1610 are routed to photosensitive beneath the quadrants 1606 and 1610, respectively, designated for green. A focus issue may be detected based on the phase or spatial distribution of the example green photons arriving at the image pixel 212. For example, based on the routing described with respect to FIG. 16, the resulting phase or spatial distribution may be more heavily weighted on one side the horizontal dashed line 1602 than the other. The precise phase imbalance may further be determined based on the location of the image pixel 212 within the overall pixel array 210, the orientation of the image pixel 212 to the scene, and/or the extent the scene is out of focus. As a result, by detecting a phase or spatial imbalance across the example horizontal dashed line 1602 associated with the image pixel 212 of FIG. 16, the magnitude and location of the phase imbalance may be used to automatically adjust focus of the lens(es) 104 (FIG. 1) of the camera module 102 (FIG. 1).

In the example PDAF considerations discussed with respect to FIG. 16, green was the example PDAF color. Because the example image pixel 212 has RGGB sensitivity, equal numbers of discrete green photosensitive regions reside beneath each quadrant of the color router 400. Alternatively, for the example RGGB sensitive, either red or blue may be selected as the PDAF color. Considering red as the designated PDAF color, the example image pixel 212 has equal number of discrete red photosensitive regions in the quadrants 1604 and 1608. Equivalently stated, when divided by horizontal line 1602, a top sub-section of the example image pixel 212, including quadrants 1604 and 1606, has equal number of discrete red photosensitive regions to a bottom subsection, including quadrants 1608 and 1610. Thus, a PDAF color need not have equal numbers of discrete photosensitive regions in all four quadrants.

In some examples, the image pixel may be associated with a collimator or other means of reducing an angle of incidence of incoming photons. As alluded to above, the ability of the color router 400 to perform the wavelength- and/or location-based routing may be impaired when the photon impinges upon the router collection area with a high angle of incidence. Reducing the angle of incidence of incoming photons to a color router may therefore improve routing efficiency.

FIG. 17 shows a cross-sectional view of an example image pixel 212. In particular, the cross-sectional view of the image pixel 212 depicts four photosensitive regions 1700, 1702, 1704, and 1706. The photosensitive regions 1700, 1702, 1704, and 1706 could be any combination of the color sensitivities, such as those discussed above. Residing above the photosensitive regions 1700, 1702, 1704, and 1706 is the color router 400. The example image pixel 212 further defines a collimator 1710 disposed above the color router 400. In the example shown, the collimator 1710 abuts the color router 400, but in other cases one or more additional layers, such as oxide layers, may reside between the collimator 1710 and the color router 400.

As the name implies, the collimator 1710 is designed and constructed to at least partially collimate the photons collected by collimator 1710 before those photons are incident upon the router collection area 410. Stated otherwise, the collimator 1710 is designed and constructed to modify the angle of incidence of at least some photons prior to those photons being incident upon the router collection area 410. The collimator 1710 may take any suitable form, such as a set of parallel walls that form grid pattern. The collimator may be designed and constructed of a plurality of three-dimensional structures, such as cuboids, or of materials having varying indices of refraction and/or different sizes. For example, the three-dimensional structures of the collimator layer may be selectively made of silicon dioxide and silicon nitride to modify the angle of incidence.

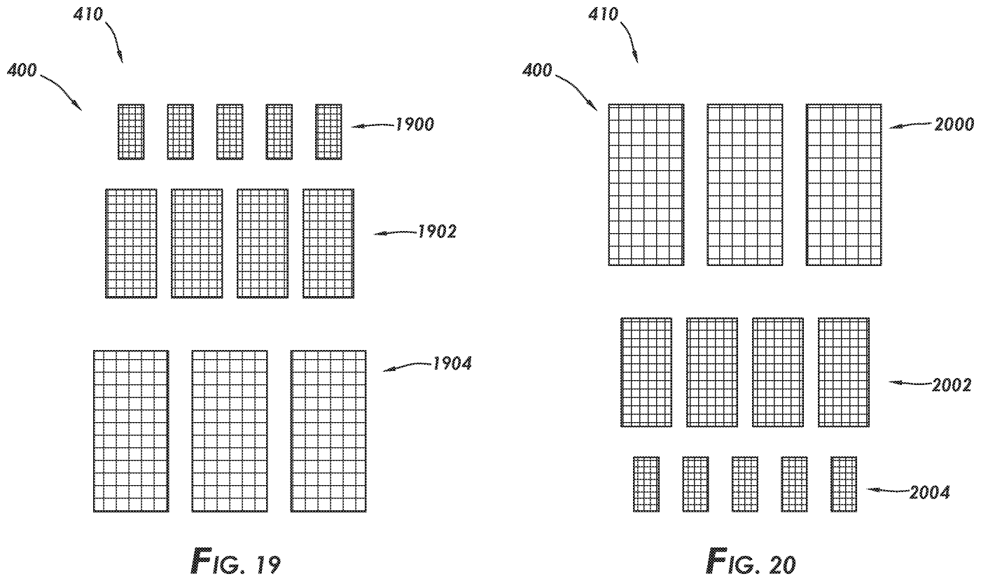

FIG. 18 shows one example collimator 1710 in the form of microlenses. FIG. 18 defines the same underlying components as FIG. 17. However, in FIG. 18, the collimator 1710 is illustratively shown as microlenses 1800 and 1802. That is, the example microlens 1800 is disposed above the color router 400 directly above photosensitive regions 1700 and 1702. The example microlens 1802 is disposed above the color router 400 directly above photosensitive regions 1704 and 1706. While the example of FIG. 18 shows each microlens associated with at least two photosensitive regions, a given microlens may be associated with any non-zero number photosensitive regions. For example, a single microlens may span one photosensitive region, one image pixel 212, or a plurality of image pixels. Moreover, the distribution of microlenses over a pixel array 210 (FIG. 2), which may include hundreds or thousands of image pixels 212, may be non-uniform. For example, the lenses 104 (FIG. 1) may tend to better collimate the photons incident on the center of the pixel array 210 than at the periphery. In such cases, a center area of the pixel array 210 may have little to no collimators 1710 in the form of microlenses, but the density of microlenses per unit area of the pixel array 210 may increase with increasing distance from the center of the pixel array 210. The increase in density may be linear, exponential, or other.

Turning to the design considerations for the color router 400, as noted above, the color router 400 may take any suitable form. In many cases, the color router 400 is constructed of several levels or layers, where each layer is designed and constructed to perform at least a partial routing. Each layer may be designed and constructed of a plurality of three-dimensional structures of materials having varying indices of refraction and/or different sizes. For example, the three-dimensional structures may be cuboids or other forms. The materials may include dielectrics and/or metallic materials. In order to reduce complexity of the construction, constraints may be placed on size of the elements that make up each layer of the color router.

FIG. 19 shows an exploded side-elevation view of an example color router 400. In particular, the example color router 400 includes three levels or layers 1900, 1902, and 1904. While three representative layers are shown, a color router 400 may contain two or more layers, and thus showing three such layers in FIG. 19 shall not be construed as a limitation. The layer 1900 is the first layer to receive the incoming photons, and thus router collection area 410 may be defined by the upper surfaces of the layer 1900. The example layer 1902 resides between the layers 1900 and 1904. Finally, the example layer 1904 defines the lowest layer, and the bottom surface of the layer 1904 outputs the routed photons to the collection areas of the photosensitive regions of the image pixel (not shown in FIG. 19).

In example cases, each layer is made of cuboids of a particular size or volume. For example, each cuboid of the layer 1900 defines a first size or first volume. Each cuboid of the layer 1902 defines a second size or second volume larger than the first size or the first volume. Each cuboid of the layer 1904 defines a third size or third volume larger than the second size or the second volume. The size change of the cuboids in each layer may be in any order, even though the example of FIGS. 19-20 show a linear change in size of the cuboids. Though only three illustrative layers are shown in the example of FIG. 19, each additional layer lower in the color router 400 may be constructed of cuboids of larger size or larger volume than the layer above. The size or volume for each layer may be set based on set constraints that may reduce complexity of the construction of the color router during semiconductor manufacture or processing. In other examples, a different combination of cuboid size or volume in a given layer may be used.

In some cases, the cuboids of each example layer are made of the same material, such as silicon oxide, silicon nitride, or titanium oxide, embedded in a lower refractive index material, such as silicon oxide and/or air. In other cases, however, the cuboids of each layer may be made of different materials than the layer above and/or below. For example, a particular layer may be made of oxide, and an abutting layer may be made of nitride, and yet another layer may be made of metal, such as gold or silver. Keeping the material of the cuboids the same on each layer may make the design and/or construction of the color router 400. In other examples, a different combination of materials in a given layer may be used.

FIG. 20 shows an exploded side-elevation view of another example color router 400. In particular, the example color router 400 of FIG. 20 includes three levels or layers 2000, 2002, and 2004. While three representative layers are shown, a color router 400 may contain two or more layers, and thus showing three such layers in FIG. 20 shall not be construed as a limitation. The layer 2000 is the first layer to receive the incoming photons, and thus router collection area 410 may be defined by the upper surfaces of the layer 2000. The example layer 2002 resides between the example layer 2000 and 2004. Finally, the example layer 2004 defines the lowest layer, and the bottom surface of the layer 2004 outputs the routed photons to the collection areas of the photosensitive regions of the image pixel (not shown in FIG. 20).

As before, each layer in FIG. 20 is made of cuboids of a particular size or volume, but the size pattern is reversed from that of FIG. 19. For example, each cuboid of the layer 2000 defines a first size or first volume. Each cuboid of the layer 2002 defines a second size or second volume smaller than the first size or the first volume. Each cuboid of the layer 2004 defines a third size or third volume smaller than the second size or the second volume. The size change of the cuboids in each layer may be in any order, even though the example of the figures show a linear change in size of the cuboids. Though only three illustrative layers are shown in the example of FIG. 20, each additional layer lower in the color router 400 may be constructed of cuboids of smaller size or smaller volume than the layer above. The size or volume for each layer may be set based on set constraints that may reduce complexity of the construction of the color router during semiconductor manufacture or processing. In other examples, a different combination of cuboid size or volume in a given layer may be used.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An image sensor comprising:
a plurality of image pixels, each image pixel comprising:
a color router defining a router collection area on an upper surface;
a first photosensitive region beneath the color router;
a second photosensitive region beneath the color router;
a third photosensitive region beneath the color router; and
the color router configured to route photons of a first wavelength received at the router collection area to the first photosensitive region, route photons of a second wavelength received at the router collection area to the second photosensitive region, and route photons of a third wavelength received at the router collection area to the third photosensitive region.

2. The image sensor of claim 1:
wherein when the color router routes photons of a first wavelength, the color router is further configured to route photons having a wavelength corresponding to red to the first photosensitive region;
wherein when the color router routes photons of a second wavelength, the color router is further configured to route photons having a wavelength corresponding to yellow to the second photosensitive region; and
wherein when the color router routes photons of a third wavelength, the color router is further configured to route photons having a wavelength corresponding to cyan to the third photosensitive region.

3. The image sensor of claim 1 further comprising:
the first photosensitive region defining a first collection area;
the second photosensitive region defining a second collection area smaller than the first collection area;
the third photosensitive region defining a third collection area smaller than the second collection area; and
wherein the first wavelength is longer than the second wavelength, and the second wavelength is longer than the first wavelength.

4. The image sensor of claim 3 further comprising:
a fourth photosensitive region beneath the color router, the fourth photosensitive region defining a fourth collection area larger than the first collection area;
wherein the color router is configured to route photons of a fourth wavelength to the fourth photosensitive region, the fourth wavelength longer than the first wavelength.

5. The image sensor of claim 1 wherein each image pixel defines a long dimension measured parallel to the router collection area, and each image pixel further comprises:
the first photosensitive region defines a collection area defining first shape;
the second photosensitive region defines a collection area defining second shape;
the third photosensitive region defines a collection area defining third shape;
wherein the first shape, the second shape, and the third shape are configured such that the longest horizontal distance a photon is routed through the color router is half the long dimension.

6. The image sensor of claim 1 further comprising:
the color router defines a first quadrant and a second quadrant;
the first photosensitive region defines a composite collection area made up of a plurality of discrete photosensitive regions, and wherein the plurality of discrete photosensitive regions are equally divided beneath the first quadrant and the second quadrant;
wherein the color router is further configured to route photons of the first wavelength that arrive within the first quadrant to discrete photosensitive regions directly beneath the first quadrant, and to route photons of the first wavelength that arrive within the second quadrant to discrete photosensitive regions directly beneath the second quadrant.

7. The image sensor of claim 1 further comprising a collimator disposed above the color router.

8. An imaging system comprising:
an imaging controller;
a camera module comprising:
a lens system coupled to the imaging controller;
a plurality of image pixels in operational relationship to the lens system and communicatively coupled to the imaging controller, each image pixel comprising:
a color router defining a router collection area on an upper surface;
a first photosensitive region beneath the color router;
a second photosensitive region beneath the color router;
a third photosensitive region beneath the color router; and
the color router configured to route photons of a first wavelength received at the router collection area to the first photosensitive region, route photons of a second wavelength received at the router collection area to the second photosensitive region, and route photons of a third wavelength received at the router collection area to the third photosensitive region.

9. The imaging system of claim 8:
wherein when the color router routes photons of a first wavelength, the color router is further configured to route photons having a wavelength corresponding to red to the first photosensitive region;
wherein when the color router routes photons of a second wavelength, the color router is further configured to route photons having a wavelength corresponding to yellow to the second photosensitive region; and
wherein when the color router routes photons of a third wavelength, the color router is further configured to route photons having a wavelength corresponding to cyan to the third photosensitive region.

10. The imaging system of claim 8 further comprising:
the first photosensitive region defining a first collection area;
the second photosensitive region defining a second collection area smaller than the first collection area;
the third photosensitive region defining a third collection area smaller than the second collection area; and
wherein the first wavelength is longer than the second wavelength, and the second wavelength is longer than the first wavelength.

11. The imaging system of claim 10 further comprising:
a fourth photosensitive region beneath the color router, the fourth photosensitive region defining a fourth collection area larger than the first collection area;
wherein the color router is configured to route photons of a fourth wavelength to the fourth photosensitive region, the fourth wavelength longer than the first wavelength.

12. The imaging system of claim 8 wherein each image pixel defines a long dimension measured parallel to the router collection area, and each image pixel further comprises:
the first photosensitive region defines a collection area defining first shape;
the second photosensitive region defines a collection area defining second shape;
the third photosensitive region defines a collection area defining third shape;
wherein the first shape, the second shape, and the third shape are configured such that the longest horizontal distance a photon is routed through the color router is half the long dimension.

13. The imaging system of claim 8 further comprising:
the color router defines a first quadrant and a second quadrant;
the first photosensitive region defines a composite collection area made up of a plurality of discrete photosensitive regions, and wherein the plurality of discrete photosensitive regions are equally divided beneath the first quadrant and the second quadrant;
wherein the color router is further configured to route photons of the first wavelength that arrive within the first quadrant to discrete photosensitive regions directly beneath the first quadrant, and to route photons of the first wavelength that arrive within the second quadrant to discrete photosensitive regions directly beneath the second quadrant.

14. The imaging system of claim 8 further comprising a collimator disposed above the color router.

15. A method of operating an image sensor, the method comprising:
directing photons from a scene into a color router positioned above a plurality of photosensitive regions;
routing, by the color router, photons of a first wavelength to a first photosensitive region beneath the color router;
routing photons of a second wavelength to a second photosensitive region beneath the color router; and
routing photons of a third wavelength to a third photosensitive region beneath the color router.

16. The method of claim 15 wherein the first wavelength corresponds to red, the second wavelength corresponds to yellow, and the third wavelength corresponds to cyan.

17. The method of claim 15 further comprising:
the first photosensitive region defining a first collection area;
the second photosensitive region defining a second collection area smaller than the first collection area;
the third photosensitive region defining a third collection area smaller than the second collection area; and
wherein the first wavelength is longer than the second wavelength, and the second wavelength is longer than the third wavelength.

18. The method of claim 17 further comprising routing, by the color router, photons of a fourth wavelength to a fourth photosensitive region, the four photosensitive region defining a fourth collection area larger than the first collection area.

19. The method of claim 15 wherein each image pixel defines a long dimension measured parallel to a router collection area of the color router, and wherein:
routing photons of the first wavelength further comprises horizontally routing the photons of the first wavelength no more than three-quarters of the long dimension to reach the first photosensitive region;
routing photons of the second wavelength further comprises horizontally routing the photons of the second wavelength no more than three-quarters of the long dimension to reach the second photosensitive region; and
routing photons of the third wavelength further comprises horizontally routing the photons of the third wavelength no more than three-quarters of the long dimension to reach the third photosensitive region.

20. The method of claim 15 further comprising collimating photons between the scene and the color router.
